(19) United States
(12) Patent Application Publication
(10) Pub. No.: US 2025/0037976 A1
(43) Pub. Date: Jan. 30, 2025

(54) PROCESS STACK FOR CVD PLASMA TREATMENT

(71) Applicant: Applied Materials, Inc., Santa Clara, CA (US)

(72) Inventors: Anirudh K. Alewoor, Bangalore (IN); Akshay Dhanakshirur, Hubli (IN); Mayur Govind Kulkarni, Bangalore (IN)

(73) Assignee: Applied Materials, Inc., Santa Clara, CA (US)

(21) Appl. No.: 18/227,767

(22) Filed: Jul. 28, 2023

(51) Int. Cl. H01J 37/32; C23C 16/44

(52) U.S. Cl. CPC H01J 37/32458; C23C 16/4412; H01J 37/3244; H01J 37/32642; H01J 37/32715; H01J 2237/3321

(57) ABSTRACT

Gas distribution assemblies, processing chambers, and methods for processing substrates are provided. A substrate processing chamber includes a chamber body having a first end and a second end, a lid coupled to the first end of the chamber body, an isolator disposed on an upper surface of the lid, a faceplate disposed on an upper surface of the isolator, a substrate support disposed on a shaft extending through the second end of the chamber body, a pumping ring positioned within the chamber body, and an exhaust outlet in fluid communication with a system foreline and the plurality of apertures. The processing chamber defines a processing region between the substrate support and the faceplate. The pumping ring includes a flange extending in a plane generally parallel with a top surface of the substrate support that defines a plurality of apertures.

### TECHNICAL FIELD

The present technology relates to components and apparatuses for semiconductor manufacturing. More specifically, the present technology relates to processing chamber components and other semiconductor processing equipment.

### BACKGROUND OF THE INVENTION

Integrated circuits are made possible by processes which produce intricately patterned material layers on substrate surfaces. Producing patterned material on a substrate requires controlled methods for deposition, expansion, and removal of materials. However, with new processing designs, producing high quality layers of material may be challenging. For instance, in certain processing methods, there may be large pressure transitions within the processing region when utilizing the same processing chamber to cycle between different processing methods. This pressure transition may include a pressure transition period where gas flows out of the processing region. During this pressure transition period, undesirable byproducts within the chamber body may inadvertently interact with the substrate being formed.

Thus, there is a need for improved systems and methods that can be used to produce high quality devices and structures. These and other needs are addressed by the present technology.

### BRIEF SUMMARY OF THE INVENTION

The present technology is generally directed to gas distribution assemblies, processing chambers, and methods for processing substrates. A substrate processing chamber includes a chamber body having a first end and a second end, a lid coupled to the first end of the chamber body, an isolator disposed on an upper surface of the lid, a faceplate disposed on an upper surface of the isolator, a substrate support disposed on a shaft extending through the second end of the chamber body, a pumping ring positioned within the chamber body, and an exhaust outlet in fluid communication with a system foreline and the plurality of apertures. The processing chamber defines a processing region between the substrate support and the faceplate. The pumping ring includes a flange extending in a plane generally parallel with a top surface of the substrate support that defines a plurality of apertures.

In embodiments, the flange includes a first section and a second section, where the first section defines a first portion of apertures of the plurality of apertures and the second section defines a second portion of apertures of the plurality of apertures; and the first section defines a first sectional void volume based on the first portion of apertures and the second section defines a second sectional void volume based on the second portion of apertures, wherein the first sectional void volume is less than the second sectional void volume. In more embodiments, the first section is closer to the exhaust outlet than the second section. Furthermore, in embodiments, the first portion of apertures includes a lesser number of apertures than the second portion of apertures. In embodiments, the first portion of apertures includes an equal number of apertures as the second portion of apertures. Moreover, in some embodiments, each aperture of the first portion of apertures includes a lesser void volume than each aperture of the second set of apertures. In embodiments, the processing system includes a pumping support disposed between the pumping ring and the chamber body, where the pumping support defines a pumping channel in fluid communication with the plurality of apertures, and a pumping exit in fluid communication with the pumping channel and the system foreline. In some embodiments, a bottom surface of the isolator is generally coplanar with a bottom surface of the faceplate. Furthermore, in embodiments, the isolator includes an isolator body and an isolator extension extending from the isolator body at an angle, where the isolator extension forms the bottom surface of the isolator.

The present technology is also generally directed to a gas distribution assembly. The gas distribution assembly includes a pumping ring having a ring body, a transition portion, and a flange extending transverse from the ring body. The flange defines a plurality of apertures extending from a top surface of the flange to a bottom surface of the flange. The flange includes a first section and a second section. The first section of the flange defines a first portion of apertures of the plurality of apertures and the second section of the flange defines a second portion of apertures of the plurality of apertures. The first section defines a first sectional void volume based on the first portion of apertures and the second section defines a second sectional void volume based on the second portion of apertures, where the first sectional void volume is less than the second sectional void volume. The gas distribution assembly also includes an isolator having a base portion, a body portion, and an extension portion. The extension portion of the isolator is disposed above and generally parallel to the transition portion of the pumping ring.

In embodiments, at least one aperture of the plurality of apertures includes a frustoconical shape. In more embodiments, the flange includes a top surface and a bottom surface, and the top surface defines a first width of the at least one aperture and the bottom surface defines a second width of the at least one aperture, the first width being smaller than the second width. Furthermore, in embodiments, the first portion of apertures includes a lesser number of apertures than the second portion of apertures. In yet more embodiments, the first portion of apertures includes an equal number of apertures as the second portion of apertures. Additionally or alternatively, in embodiments, each aperture of the first portion of apertures includes a lesser void volume than each aperture of the second portion of apertures. In embodiments, the flange further includes a third section positioned between the first and second sections, where the third section defines a third portion of apertures of the plurality of apertures, and the third section defines a third sectional void volume based on the third portion of apertures, where the third sectional void volume is less than the second sectional void volume and greater than the first sectional void volume. In yet more embodiments, the third portion of apertures includes a lesser number of apertures than the second portion of apertures and a greater number than the first portion of apertures. Moreover, in embodiments, the third portion of apertures includes an equal number of apertures as at least one of the first or second portion of apertures. In embodiments, each aperture of the third portion of apertures includes a lesser void volume than each aperture of the at least one of the first or second portion of apertures.

The present technology is also generally directed to methods of semiconductor processing. Methods include flowing a carbon-containing precursor into a processing chamber and exhausting a gas from the chamber body of the processing chamber via a pumping ring to the exhaust outlet. In methods, the processing chamber includes a chamber body having a first end and a second end, a lid coupled to the first end of the chamber body, an isolator disposed on an upper surface of the lid, a faceplate disposed on an upper surface of the isolator, a substrate support disposed on a shaft extending through the second end of the chamber body, a pumping ring positioned within the chamber body, and an exhaust outlet in fluid communication with a system foreline and the plurality of apertures. Processing chambers include where a processing region is defined between the substrate support and the faceplate. Methods include where the pumping ring has a flange extending in a plane generally parallel with a top surface of the substrate support, the flange defining a plurality of apertures.

Such technology may provide numerous benefits over conventional systems and techniques. For example, the processes and devices may reduce the number of defects formed on substrates when conducting two or more processes in a processing chamber. Namely, the processes and devices may significantly improve the types of processes and pressures able to be conducted in a single chamber, improving substrate throughput and electrical properties. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top-down schematic view of a processing chamber according to embodiments of the present technology.

FIG. 2 shows a cross-sectional schematic side view of a processing chamber according to embodiments of the present technology.

FIG. 3 shows a partial cross-sectional side view of a processing chamber according to embodiments of the present technology.

FIG. 4 shows a partial cross-sectional view of a process stack according to embodiments of the present technology.

FIG. 5 shows an isometric view of a pumping ring according to embodiments of the present technology.

FIG. 6 shows operations of an exemplary method of semiconductor processing according to some embodiments of the present technology.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION OF THE INVENTION

As device features reduce in size, tolerances across a substrate surface may be reduced, and material property differences across a film may affect device realization and uniformity. Many processing chambers include asymmetric exhausting systems, where gases are not exhausted from the processing chambers uniformly from all sides of the chamber, creating a skew in the outflow of gases. For example, a single-exhaust plasma-enhanced chemical vapor deposition (PECVD) chamber may include a foreline conduit (for exhausting gases from the chamber body) that is disposed along one side of the chamber, causing a skew in gas flow toward that side. This skew may create nonuniformity of gas flow throughout the chamber, which may produce nonuniformity of gas flow across a substrate. This nonuniformity of gas flow may create film uniformity differences across the substrate for materials produced or removed. That is, the resulting substrate may be characterized by varied thickness of depositions or varied film properties across the surface of the substrate. Such variance may be undesirable and may ultimately lead to semiconductor failures.

In addition, certain types of substrate processing methods benefit from cycling between high and low pressures processes within the processing region. For example, it is often desirable to perform vapor deposition and plasma deposition processes within the same processing chamber. Chemical vapor deposition (CVD) methods generally utilize pressures at atmospheric pressure or slightly below (e.g., 500 Torr). However, plasma processes are conducted at higher vacuum, lower pressure environments (e.g., 5-10 Torr). Many existing systems are not suited for such large pressure variations within the same processing chamber. Thus, when utilizing conventional systems and methods, undesirable byproducts may enter the processing region through holes in the pumping ring during such pressure transitions, resulting in defects formed on the substrate surface.

In conventional systems, pumping rings in a processing stack define holes extending laterally out of the processing region for the removal of processes gasses. In this configurations, process gas flow from these holes in a horizontal flow path with little to no resistance to ambient flow. Such a horizontal flow path places the substrate directly below the flow path such that any undesirable byproducts caught in the flow path may deposit directly onto the substrate from the differences in pressure exhibited when cycling between process steps. As such, during the pressure transitions, byproducts may land on the substrate as the gas is being exhausted out of the processing region.

The present technology overcomes these and other problems by providing a pumping ring that alters the flow path of process gasses to significantly reduce or even eliminate substrate defects due to pressure transitions within a processing chamber. For instance, the flow path of process gasses may be altered by a pumping ring in an updated process stack having vertically extending apertures, such that the substrate is no longer in the direct flow path of gases during pressure transition periods. Specifically, a pumping ring is used with apertures that define the flow path of gases such that the gases do not flow horizontally across the substrate but vertically away from the substrate. Accordingly, the pumping ring allows for the pressure to transition within the processing region while minimizing the risk that the substrate is affected by undesirable byproducts. In addition, pumping process stacks according to the present technology provide for excellent process gas removal speeds, improved uniformity of flow throughout the chamber, and/or may also preventing parasitic light ups. Thus, process stacks according to the present technology surprisingly allow for excellent evacuation, improving throughput and allowing a large variety of process conditions to be conducted in one processing chamber.

The remaining disclosure will routinely identify specific process chambers and deposition processes utilized in conjunction with the improved processing chambers. However, it will be readily understood that the systems and methods are equally applicable to other substrates and deposition methods that would benefit from improved pressure flexibility and reduced defects during process cycling. Accordingly, the technology should not be considered to be so limited as for use with these specific devices or systems alone. The disclosure will discuss one possible semiconductor processing chamber that may include one or more components according to embodiments of the present technology before additional variations and adjustments to this apparatus according to embodiments of the present technology are described.

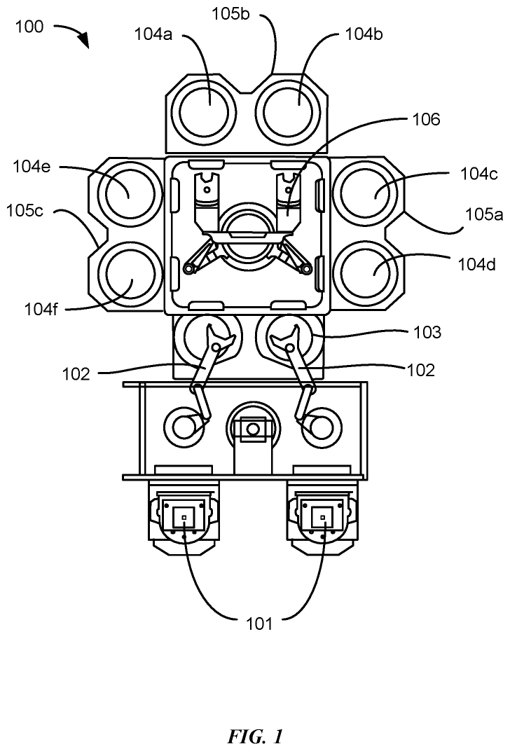

FIG. 1 shows a top plan view of one embodiment of a processing system 100 of deposition, etching, baking, and curing chambers according to embodiments. In the figure, a pair of front opening unified pods (FOUPs) 101 supply substrates of a variety of sizes that are received by robotic arms 102 and placed into a low pressure holding area 103 before being placed into one of the substrate processing chambers 104a-f, positioned in tandem sections 105a-c. A second robotic arm 106 may be used to transport the substrate wafers from the holding area 103 to the substrate processing chambers 104a-f and back. Each substrate processing chamber 104a-f can be outfitted to perform a number of substrate processing operations including cyclical layer deposition (CLD), atomic layer deposition (ALD), chemical vapor deposition (CVD), physical vapor deposition (PVD), plasma-enhanced chemical vapor deposition (PECVD), etch, pre-clean, degas, orientation, and other substrate processes. The substrate processing chambers 104a-f may include one or more system components for depositing, annealing, curing and/or etching. Any one or more of the processes described herein may be carried out in chamber(s) separated from the fabrication system shown in different embodiments. It will be appreciated that additional configurations of chambers 104a-f are contemplated by system 100.

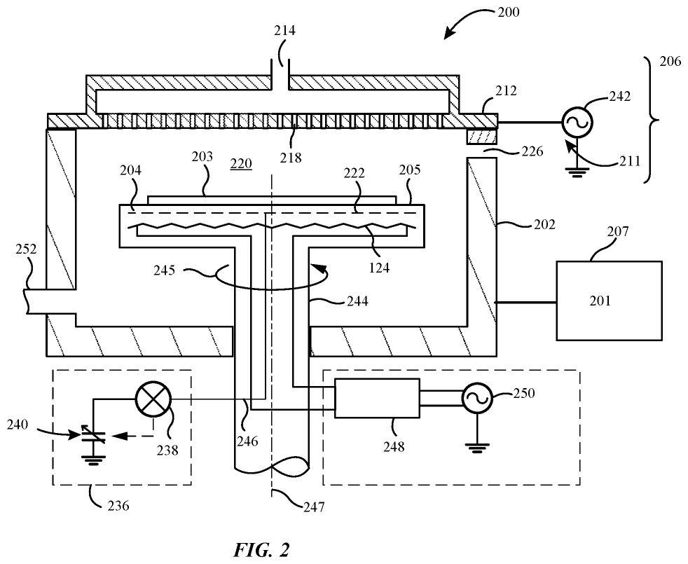

FIG. 2 shows a cross-sectional view of an exemplary processing chamber 200 according to some embodiments of the present technology. The figure may illustrate an overview of a system incorporating one or more aspects of the present technology, and/or which may be specifically configured to perform one or more operations according to embodiments of the present technology. Additional details of chamber 200 or methods performed may be described further below. Chamber 200 may be utilized to form film layers, etch material layers, form other material layers, or a combination thereof, although it is to be understood that deposition and etch methods may similarly be performed in any chamber within which deposition and etch processes may occur. The processing chamber 200 may include a chamber body 202, a substrate support 204 disposed inside the chamber body 202, and a lid assembly 206 coupled with the chamber body 202 and enclosing the substrate support 204 in a processing volume 220. A substrate 203 may be provided to the processing volume 220 through an opening 226, which may be conventionally sealed for processing using a slit valve or door. The substrate 203 may be seated on a surface 205 of the substrate support during processing. In some embodiments, the substrate support 204 may be rotatable, as indicated by the arrow 245, along an axis 247 where a shaft 244 of the substrate support 204 may be located, or may be stationary. Alternatively, the substrate support 204 may be lifted up to rotate as necessary during a deposition process.

A gas distributor 212 may define apertures 218 for distributing process precursors into the processing volume 220. The gas distributor 212 may be coupled with a first source of electric power 242, such as an RF generator, RF power source, DC power source, pulsed DC power source, pulsed RF power source, or any other power source that may be coupled with the processing chamber. In some embodiments, the first source of electric power 242 may be an RF power source.

The gas distributor 212 may be a conductive gas distributor or a non-conductive gas distributor. The gas distributor 212 may also be formed of conductive and non-conductive components. For example, a body of the gas distributor 212 may be conductive while a face plate of the gas distributor 212 may be non-conductive. The gas distributor 212 may be powered, such as by the first source of electric power 242 as shown in FIG. 2, or the gas distributor 212 may be coupled with ground in some embodiments.

The gas distributor 212 may be a conductive gas distributor or a non-conductive gas distributor. The gas distributor 212 may also be formed of conductive and non-conductive components. For example, a body of the gas distributor 212 may be conductive while a faceplate of the gas distributor 212 may be non-conductive. The gas distributor 212 may be powered, such as by the first source of electric power 242 as shown in FIG. 2, or the gas distributor 212 may be coupled with ground in some embodiments.

A first electrode 222 may be coupled with the substrate support 204. The first electrode 222 may be embedded within the substrate support 204 or coupled with a surface of the substrate support 204. The first electrode 222 may be a plate, a perforated plate, a mesh, a wire screen, or any other distributed arrangement of conductive elements. The first electrode 222 may be a tuning electrode and may be coupled with a tuning circuit 236 by a conduit 246, for example a cable having a selected resistance, such as 50 ohms, for example, disposed in the shaft 244 of the substrate support 204. The tuning circuit 236 may have an electronic sensor 238 and an electronic controller 240, which may be a variable capacitor. The electronic sensor 238 may be a voltage or current sensor and may be coupled with the second electronic controller 240 to provide further control over plasma conditions in the processing volume 220.

A second electrode 224, which may be a bias electrode and/or an electrostatic chucking electrode, may be coupled with the substrate support 204. The second electrode may be coupled with a second source of electric power 250 through a filter 248, which may be an impedance matching circuit. The second source of electric power 150 may be DC power, pulsed DC power, RF bias power, a pulsed RF source or bias power, or a combination of these or other power sources. In some embodiments, the second source of electric power 250 may be an RF bias power. The substrate support 204 may also include one or more heating elements configured to heat the substrate to a processing temperature, which may be between about 25° C. and about 800° C. or greater.

The lid assembly 206 and substrate support 204 of FIG. 2 may be used with any processing chamber for plasma or thermal processing. In operation, the processing chamber 200 may afford real-time control of plasma conditions in the processing volume 220, such as via a system controller 201 which may be contained within a processor 207. The substrate 203 may be disposed on the substrate support 204, and process gases may be flowed through the lid assembly 206 using an inlet 214 according to any desired flow plan. Gases may exit the processing chamber 200 through an outlet 252. Electric power may be coupled with the gas distributor 212 to establish a plasma in the processing volume 220. The substrate may be subjected to an electrical bias using the second electrode 224 in some embodiments.

Upon energizing a plasma in the processing volume 220, a potential difference may be established between the plasma and the first electrode 222. The electronic controller 240 may then be used to adjust the flow properties of the ground paths represented by the tuning circuit 236. A set point may be delivered to the first circuit 236 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Tuning circuit 236 may have a variable impedance that may be adjusted using the electronic controller 240. Where the electronic controller 240 is a variable capacitor, the capacitance range of each of the variable capacitors, may be chosen to provide an impedance range. This range may depend on the frequency and voltage characteristics of the plasma, which may have a minimum in the capacitance range of each variable capacitor. Hence, when the capacitance of the electronic controller 240 is at a minimum or maximum, impedance of the tuning circuit 236 may be high, resulting in a plasma shape that has a minimum aerial or lateral coverage over the substrate support. When the capacitance of the electronic controller 240 approaches a value that minimizes the impedance of the tuning circuit 236, the aerial coverage of the plasma may grow to a maximum, effectively covering the entire working area of the substrate support 204. As the capacitance of the electronic controller 240 deviates from the minimum impedance setting, the plasma shape may shrink from the chamber walls and aerial coverage of the substrate support may decline.

The electronic sensor 238 may be used to tune the circuit 236 in a closed loop. A set point for current or voltage, depending on the type of sensor used, may be installed in each sensor, and the sensor may be provided with control software that determines an adjustment to the respective electronic controller 240 to minimize deviation from the set point. Consequently, a plasma shape may be selected and dynamically controlled during processing. It is to be understood that, while the foregoing discussion is based on electronic controller 240, which may be a variable capacitor, any electronic component with adjustable characteristic may be used to provide tuning circuit 236 with adjustable impedance.

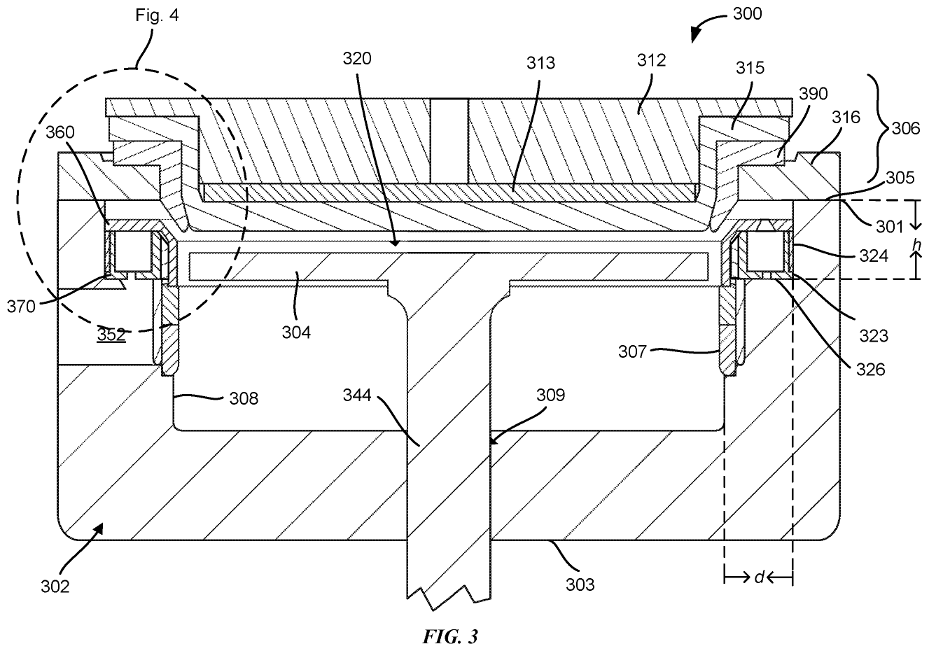

FIG. 3 shows a cross-sectional view of an exemplary processing chamber 300 according to embodiments of the present technology. It is understood that features ending in like reference numerals as features discussed above are similar, except as noted below. The processing chamber 300 includes a chamber body 302 and a lid assembly 306. The lid assembly 306 may include a lid 316, isolator 390, faceplate 315, gas box 312, and a blocker plate 313. The chamber body 302 includes a top (or first) end 301 and a bottom (or second end) 303. The lid assembly 306 may be coupled to the top end 301 of the chamber body 302. A substrate support 304 may be disposed on a shaft 344 and movably positioned in the chamber body 302 via the shaft 344 extending through a shaft opening 309 defined through the second end of the chamber body 302. A pumping support 370, pumping ring 360, a substrate support 304, and a shaft 344 are at least partially disposed within the chamber body 302. The chamber body 302, pumping ring 360, and faceplate 315 define a processing region 320 in which a substrate is processed on the substrate support 304.

In some embodiments, the chamber body 302 may include a chamber liner 307 positioned along an interior surface 308 of the chamber body 302 (e.g., an internal surface of the chamber body 302 facing towards a center of the chamber body 302). The chamber liner 307 may protect at least a portion of the interior surface 308 of the chamber body 302. The chamber liner 307 may be toroidal with a substantially rectangular cross-section and completely encircle the portion of the interior surface 308 of the chamber body 302 that the chamber liner 307 is positioned over. However, in other embodiments, the chamber liner may be partially toroidal (e.g., a quarter toroidal, half toroidal, or the like) and may encircle only a portion of the interior surface of the chamber body, and may have any cross-sectional shape corresponding to a cross-sectional shape of chamber body 302. In yet other embodiments, there may be multiple chamber liners received within the chamber body. Although the chamber liner 307 is depicted just below the pumping ring 360, in other embodiments, the chamber liner may be spaced from the pumping ring. In a yet further embodiment, the processing chamber may not include a chamber liner. The chamber body 302 may define a ledge 323 around an interior circumference of the upper surface of the chamber body 302. The ledge 323 may be sized and shaped to receive other components, such as the pumping support 370 and the pumping ring 360. Moreover, the ledge 323 may have a depth d from an interior surface 308 of the chamber body 302 to a ledge sidewall 324 that allows those components to sit within the ledge 323 such that the interior surfaces of one or more components positioned along the ledge 323 are generally coplanar with the interior surface 308 of the chamber body 302. Generally coplanar may mean that two surfaces are generally parallel and less than or about 1 μm from each other, such as less than or about 0.8 μm, such as less than or about 0.6 μm, such as less than or about 0.4 μm, such as less than or about, 0.2 μm, or about 0 m from each other. Additionally or alternatively, generally parallel may mean that the planes defined by the two surfaces vary from parallel by an angle of less than about 30°, such as less than or about 20°, such as less than or about 10°, such as less than or about 5°, such as less than or about 2.5°, such as less than or about 1º, or such as about 0°. However, in other embodiments, the ledge may have any desired depth. The ledge 323 may be defined along an upper portion of the chamber body 302, such as extending from below a top end 301 of the chamber body 302, and may therefore define a height h extending from the top end 301 of the chamber body 302 to a bottom surface 326 of the ledge. However, in other embodiments, the ledge may be defined along any portion of the chamber body, including a bottom portion of the chamber body.

As discussed above, certain types of substrate processing methods benefit from cycling between high and low pressures processes within the processing region 320. For example, certain methods may include cycling between chemical vapor and deposition processes, which may include cycling between different levels of pressure within the processing region 320 (e.g., between 5 and 500 Torr, as an example only). During this process cycling, there may be a risk that undesirable byproducts may be left within the processing region 320 to fall on a substrate being formed on the substrate support 304. As will be discussed further below, the pumping ring 360 and the pumping support 370 minimizes the risk that such undesirable byproduct falls onto the substrate by defining a process gas flow path away from the substrate.

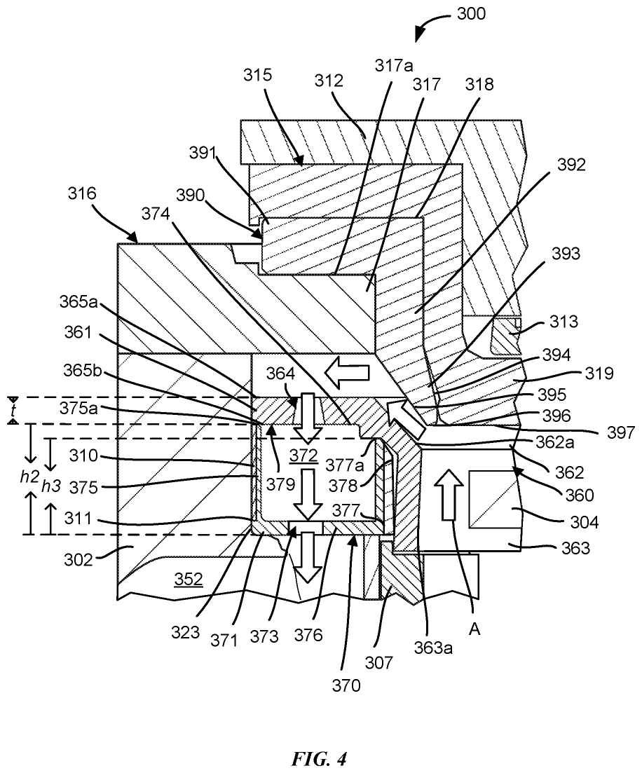

Turning to FIG. 4, the pumping support 370 may be positioned within the ledge 323 between the pumping ring 360 and the chamber body 302. The pumping ring 360, pumping support, and chamber body 302 may be coupled together 302 through welding, adhesive, releasable or non-releasable fastening, or the like. The pumping support 370 includes a channel body 371 sized and shaped to be supported by ledge 323 while providing an upper surface 374 on which the pumping ring 360 may be seated. For example, the channel body 371 may be toroidal with a substantially circular cross-section, however, in other embodiments, the channel body may have any other geometric shape, such as a shape of the chamber body 302 and/or pumping ring 360. The channel body 371 includes a bottom wall 376, inner sidewall 377, and outer sidewall 375. The bottom wall 376 is sized to sit on the ledge 323 in embodiments, and provide support between the chamber body 302 and the ring body 363. The inner sidewall 377 includes a surface 378 facing the processing region 320 shaped and sized to support the pumping ring 360 when seated on pumping support 370. The outer sidewall 375 extends a height h2 from the bottom wall 376 to a top surface 375a of outer sidewall 375 to provide support to the flange 361, and the inner sidewall 377 extends a height h3 from the bottom wall 376 to a top surface 377a of inner sidewall 377. In embodiments, the inner sidewall 377 height h3 may be less than the outer sidewall 375 height h3 to support transition portion 362 and ring body 363. However, in other embodiments, the heights of the inner sidewall and the outer sidewall may be generally equal, or the height of the inner sidewall may be greater than the height of the outer sidewall.

In embodiments, the outer sidewall 375 and the bottom wall 376 may define a ledge 311 to receive another component, such as insulative liner 310. The insulative liner 310 may be toroidal with a substantially circular cross-section that, when positioned within the support ledge 311, provides isolation, such as thermal isolation in an embodiment, between the chamber body 302 and the outer sidewall 375. For instance, in embodiments, a thermal liner may retain heat in the pumping ring, decreasing the likelihood of deposition of byproducts due to a large thermal difference between the processing region and the chamber body. However, in other embodiments, there may be no insulative liner or the insulative liner may have any one or more of the geometries discussed above. For example, the pumping support may not define a ledge and, instead, the outer sidewall of the pumping support may extend from the bottom wall uninterrupted to support the flange of the pumping ring.

The pumping support 370 may define a pumping channel 372 extending circumferentially around the pumping support 370 between the outer sidewalls 375, the inner sidewalls 377, and the bottom wall 376. The pumping channel 372 may include a top opening 379 having a width that extends between the top surface 375a of the outer sidewall 375 and the top surface 377a of the inner sidewall 377. However, in other embodiments, the pumping support may include a top wall that defines the top opening to have a width less than the distance between the outer sidewall and the inner sidewall. In this example, the support opening may still circumferentially extend around the pumping support, however, the top opening includes a smaller width than what is shown in FIG. 4.

The bottom wall 376 defines a pumping support exit 373 along a portion of the bottom wall 376. The pumping support exit 373 may be an aperture having a cylindrical shape and/or a shape corresponding to a shape of one or more of the plurality of apertures of the pumping ring 360, as described further below. However, in other embodiments, the pumping exit may have any other shapes, including being ovoid, rectangular, triangular, a slit-shape, or the like. The pumping support exit 373 may be defined to be along the bottom wall 376 on a portion of pumping support 370 at a location above gas exhaust outlet 352 of the chamber body 302. In other embodiments, there may be more than one pumping exit (e.g., where there is more than one outlet). As will be discussed further below, the pumping support exit 373, pumping channel 372, and top opening 379 may facilitate the outlet 352 and the processing region 320 being in fluid communication with one another through the pumping ring 360. The outlet 352 of the chamber body 302 may be in fluid communication with an exhaust system (not shown) coupled to a vacuum source to pump gas from the processing region 320. In this manner, gas may flow freely between the processing region 320 and the outlet 352 to the vacuum source along a gas flow path A, as shown by the arrows in FIG. 4 and as will be described further below.

In embodiments, the pumping ring 360 may be sized and shaped to be received within the chamber body 302, and to sit on one or more other components (e.g., the pumping support 370). The pumping ring 360 may be made from any suitable material (e.g., aluminum, alumina, aluminum nitride, in embodiments, or other materials as known in the art). Turning to FIG. 4, the pumping ring 360 may include a ring body 363, a transition portion 362, and a flange 361. The ring body 363 may be sized and shaped such that, when the pumping ring 360 is positioned within the chamber body 302, a surface 363a of the ring body 363 facing the processing region 320 may be generally coplanar with the interior surface 308 of the chamber body 302. For example, the ring body 363 may have a toroidal shape, or any other geometry as discussed above. However, in other embodiments, the ring body may have any other size (e.g., such that an interior surface of the ring body is not coplanar with an interior surface of the chamber body) and shape (e.g., cuboid, or the like). The ring body 363 may have an internal diameter greater than or about 10 inches, such as greater than about 12 inches, such as greater than or about 13 inches, or may have an internal diameter less than or about 14 inches.

The transition portion 362 may extend at a an angle greater than or about 15°, greater than or about 20°, greater than about 25°, greater than or about 30° greater than or about 35°, greater than or about 40°, greater than or about 42.5°, or may include an angle less than or about 75°, such as less than or about 70°, such as less than or about 65°, such as less than or about 60°, such as less than or about 55°, such as less than or about 50°, such as less than or about 47.5°, or any ranges or values therebetween, from ring body 363. This range of angles may be beneficial to allow for process gas to more efficiently flow (e.g., flow with less interruptions) over the transition portion 362, enabling more efficient evacuation of the process gas, as will be discussed further below, as gas flows from the processing region 320 through the pumping ring 360 to pumping support 370.

The transition portion 362 may have a surface 362a facing the isolator 390. As illustrated, in embodiments, the isolator 390 may have a lower surface having a linear slant, as will be discussed further below. In embodiments, the linear slant may mirror the angle of the transition portion 362, and therefore be generally parallel to the surface of the isolator 390 (i.e., the surface 395 of the isolator extension 393). Such a linear slant may allow for process gas to more efficiently flow over the transition portion 362 from the processing region 320. However, in other embodiments, the surface of the transition portion facing the isolator and/or lower surface 395 of the isolator may have a concave or convex curved surface, which may mirror one another, or have different surface profiles. In yet further embodiments, the transition portion may have multiple surfaces that are curved and/or linear. In this example, each of these surfaces may be angled with respect to each other to form complex shapes (e.g., to form a step-wise surface or to form a generally curved surface) that, collectively, defines the surface of the transition portion facing the isolator. In other embodiments, the pumping ring may not include a transition portion and, instead, may only include the ring body and the flange substantially orthogonally extending from each other.

Similarly, the isolator extension 393 may define an exterior surface 395 facing the pumping ring 360. The exterior surface 395 may be angled relative to the isolator wall 392 to define a portion of a gas flow path between the isolator extension 393 and the transition portion 362 of the pumping ring 360. For example, the exterior surface 395 may extend at an angle greater than or about 15°, greater than or about 20°, greater than about 25°, greater than or about 30° greater than or about 35°, greater than or about 40°, greater than or about 42.5°, or may include an angle less than or about 75°, such as less than or about 70°, such as less than or about 65°, such as less than or about 60°, such as less than or about 55°, such as less than or about 50°, such as less than or about 47.5°, or any ranges or values therebetween, from the ring body 363. The distance between the exterior surface 395 and the transition portion 362 may be greater than or about 0.1 inches, such as greater than or about 0.15 inches, such as greater than or about 0.2 inches, or may be less than 0.5 inches, such as less than or about 0.4 inches, such as less than or about 0.3 inches, or any ranges or values therebetween. In some embodiments, the distance between the exterior surface 395 and the transition portion 362 may increase further away from the center of the processing region 320. However, in other embodiments, there may be no change in distance between the exterior surface of the isolator extension and the transition portion. In a yet further embodiment, the distance between the exterior surface of the isolator extension and the transition portion may decrease further away from the center of the processing region.

These angles and distances may allow for gas to efficiently flow between the isolator 390 and the pumping ring 360 during a transition from a high and low pressure without unduly hindering flow speed. At the same time, the isolator 390 may act as a barrier between the faceplate 315 and the lid 316 to minimize parasitic plasma build-up along the lid 316. Accordingly, these angles and distances may be optimized to account for maximizing gas flow between the isolator 390 and the pumping ring 360 while minimizing parasitic plasma arcing between the faceplate 315 and the lid 316. Although the exterior surface 395 is depicted as being linear, in other embodiments, the exterior surface of the isolator extension may be curved, step-wise, or the like. The isolator 390 and the pumping ring 360 may be, in combination, referred to as a gas distribution assembly.

Referring back to flange 361 of pumping ring 360, the flange 361 may extend at an angle from the transition portion 362 and the ring body 363. For example, the flange 361 may be at an angle greater than or about 15°, greater than or about 20°, greater than about 25°, greater than or about 30° greater than or about 35°, greater than or about 40°, greater than or about 42.5°, or may include an angle less than or about 75°, such as less than or about 70°, such as less than or about 65°, such as less than or about 60°, such as less than or about 55°, such as less than or about 50°, such as less than or about 47.5°, or any ranges or values therebetween, from the transition portion 361. In embodiments, the flange 361 may be have an angle greater than or about 70°, such as greater than or about 75°, such as greater than or about 80°, such as greater than or about 85°, such as greater than or about 87.5°, or an angle less than or about 110°, such as less than or about 105°, such as less than or about 100°, such as less than or about 95°, such as less than or about 92.5°, or any ranges or values therebetween, to ring body 363. In embodiments, the flange 361 may be generally orthogonal to the ring body 363. The flange 361 may be generally parallel with a top surface 305 of the chamber body 302.

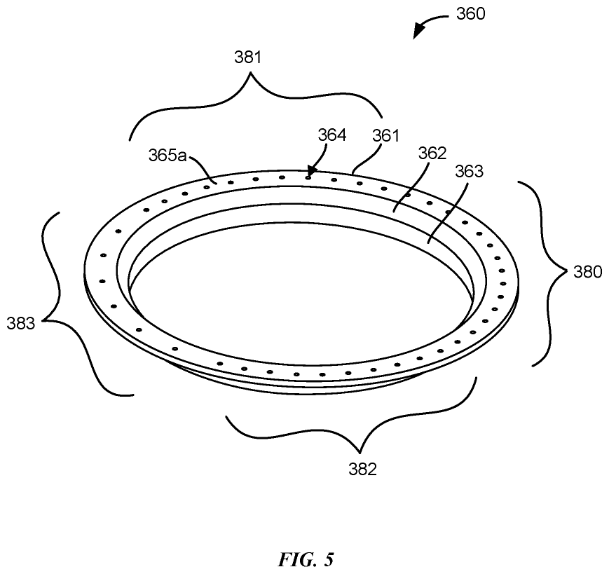

With reference to FIGS. 4 and 5, the flange 361 may include a thickness/extending between a top surface 365a and a bottom surface 365b. As illustrated, a plurality of apertures 364 extend through the thickness/of the flange 361 (e.g., extending from the top surface 365a and the bottom surface 365b of the flange 361). Thus, in embodiments, when the pumping ring 360 is installed within the chamber body 302, the plurality of apertures 364 may be defined to have a size and shape to facilitate the flow of gas from the processing region 320 over the ring body 363, over transition portion 362, and through the plurality of apertures 364. For example, in embodiments such as the embodiment as illustrated, all or a portion of the plurality of apertures 364 defined along the surfaces 365a, 365b may be defined to have a circular shape. However, in other embodiments, all or a portion of the plurality of apertures may have any other shapes, including being ovoid, rectangular, triangular, a slit-shape, or the like.

In embodiments, the thickness/may be greater than or about 0.1 cm, such as greater than or about 0.15 cm, such as greater than or about 0.2 cm, such as greater than or about 0.25 cm, such as greater than or about 0.3 cm, such as greater than or about such as greater than or about 0.35 cm, such as greater than or about 0.4 cm, such as greater than or about 0.45 cm, such as greater than or about 0.5 cm, such as greater than or about 0.55 cm, such as greater than or about 0.6 cm, such as greater than or about 0.75 cm, such as greater than or about 1 cm, or such as less than or about 1.5 cm, such as less than or about 1.25 cm, such as less than or about 1 cm, such as less than or about 0.75 cm, such as less than or about 0.7 cm, such as less than or about 0.65 cm, such as less than or about 0.6 cm or any ranges or values therebetween.

Nonetheless, it should be understood that, while any shape may be selected, in embodiments, the plurality of apertures may have a top (or first) cross-sectional width (e.g., diameter if circular) at top surface 365a and a bottom (or second) cross-sectional width at bottom surface 365b. In embodiments, both the top cross-sectional width and the bottom cross-sectional width may be generally equal and may have any one or more widths, and may define the apertures to have a generally cylindrical cross-sectional shape (e.g., if the apertures are circular).

For example, in embodiments, the top and/or bottom cross-sectional width may have a width greater than or about 0.1 cm, such as greater than or about 0.15 cm, such as greater than or about 0.2 cm, such as greater than or about 0.25 cm, such as greater than or about 0.3 cm, such as greater than or about such as greater than or about 0.35 cm, such as greater than or about 0.4 cm, such as greater than or about 0.45 cm, such as greater than or about 0.5 cm, such as greater than or about 0.55 cm, such as greater than or about 0.6 cm, such as greater than or about 0.75 cm, such as greater than or about 1 cm, such as greater than or about 1.25 cm, such as greater than or about 1.5 cm, or such as less than or about 2.5 cm, such as less than or about 2.25 cm, such as less than or about 2 cm, such as less than or about 1.75, such as less than or about 1.5 cm, such as less than or about 1.25 cm, such as less than or about 1 cm, such as less than or about 0.75 cm, such as less than or about 0.7 cm, such as less than or about 0.65 cm, such as less than or about 0.6 cm or any ranges or values therebetween.

However, in embodiments, the top cross-sectional width may be less than the bottom cross-sectional width, thus defining a conical cross-sectional shape for the apertures 364 (e.g., if the first and second cross-sectional widths are circular), allowing further tuning of the flow conductance. In such embodiments, the bottom cross-sectional width may be 30% or greater than the top cross-sectional width, such as about 50% or greater, such as about 75% or greater, such as about 100% or greater, such as about 125% or greater, such as about 150% or greater, such as about 175% or greater, such as about 200% or greater, such as about 225% or greater, such as about 250% or greater, such as about 275% or greater, such as where the bottom cross-sectional width is about 300% or greater than the top cross-sectional width.

For instance, in embodiments, the flange may define the bottom cross-sectional width to be larger than the top cross-sectional width such that the apertures are defined as having a frustoconical shape opposite that shown in FIG. 4. Although FIG. 4 depicts the apertures 364 as having a linear funnel shape, in other embodiments, the flow channel may have a curved or stepwise shape. Nonetheless, in such embodiments, the top cross-sectional width may be greater than or about 0.1 cm, such as greater than or about 0.15 cm, such as greater than or about 0.2 cm, such as greater than or about 0.25 cm, such as greater than or about 0.3 cm, such as greater than or about such as greater than or about 0.35 cm, such as greater than or about 0.4 cm, such as greater than or about 0.45 cm, such as greater than or about 0.5 cm, such as greater than or about 0.55 cm, such as greater than or about 0.6 cm, such as greater than or about 0.75 cm, such as greater than or about 1 cm, or such as less than or about 1.25 cm, such as less than or about 1 cm, such as less than or about 0.75 cm, such as less than or about 0.7 cm, such as less than or about 0.65 cm, such as less than or about 0.6 cm or any ranges or values therebetween. Moreover, the bottom cross-sectional width may be greater than or about 0.6 cm, such as greater than or about 0.75 cm, such as greater than or about 1 cm, such as greater than or about 1.25 cm, such as greater than or about 1.5 cm, such as greater than or about 1.6 cm, or such as less than or about 2.5 cm, such as less than or about 2.25 cm, such as less than or about 2 cm, such as less than or about 1.75, or any ranges or values therebetween.

Each aperture of the plurality of apertures 364 may define a void volume through the flange 361. Accordingly, the flange 361 defines a total void volume through the flange 361 corresponding to the total volume of the plurality of apertures 364. The flange 361 may be divided into one or more radially divided sections (e.g., one or more sections), such as sections 380-383, illustrated in FIG. 5, that each include a certain number of apertures of the plurality of 364. Each of the sections 380-383, therefore, define a sectional void volume corresponding to the sum total of the void volumes for each of the sections 380-383. and therefore a corresponding sectional void volume. In other embodiments, the flange may be divided into any number of sections, such as two, three, five, or the like.

The sectional void volume for each section 380-383 may be adjusted depending on the desired flow rate of gas exhausted through the selected section 380-383 of flange 361. For example, when the pumping ring 360 is installed in the chamber body 302, there may only be one gas exhaust outlet 352 for the gas being evacuated from the processing region 320. This outlet may be closer to one section of the flange 361 than another. For instance, as illustrated in FIG. 3, in embodiments, gas exhaust outlet 352 may be disposed below section 383, adjacent to sections 381 and 382, and spaced apart from section 380 (e.g., opposite section 380). But it should be understood that other orientations may be utilized herein. Accordingly, if the number of apertures and/or the sectional void volume of each section 380-383 were equal, gas flow from the processing region 320 through the plurality of apertures 364 to the gas exhaust outlet 352 may not be uniform due to higher pressures being exhibited to some of sections 380-383 adjacent to the gas exhaust outlet 352 (i.e., section 383) and less pressure at the other sections 380-383 spaced apart sections from the gas exhaust outlet 352 (i.e., section 380).

Thus in embodiments, to provide a more uniform flow rate of processes gas being exhausted through the flange 361 across each section 380-383, and minimize the pressure difference of processes gas across each section 380-383 of the flange 361, the flange 361 may define a smaller sectional void volume in one or more of the sections 380-383 disposed above or adjacent to the gas exhaust outlet 352 and a larger sectional volume in sections spaced apart, or spaced farther apart from the outlet.

For instance, FIG. 5 depicts one example of a flange 361 defining four sections 380-383. In embodiments, each of the sections include different sectional void volumes. However, in other examples, one or more of the sections 380-383 may include similar sectional void volumes (e.g., sections 381, 382). As an example only, the outlet may be disposed below section 383, adjacent to sections 381 and 382 somewhat equally, and spaced apart from section 380. In FIG. 5, differences in sectional void volumes are illustrated based on a difference in the number of apertures 364 present in each of the sections 380-383, where section 383 may contain the fewest apertures, sections 381 and/or 382 contain more apertures than section 380 (e.g., having a similar number of apertures 364), and section 380 may contain more apertures than sections 381-383. In embodiments, such as embodiments where the number of apertures is varied for one or more of the sections 380-383, the void volume of each of the apertures 364 may be generally equal. Thus, in the illustrated example, the sectional void volume for section 383 may be smaller than the sectional void volumes for each of the sections 380-382, and the sectional void volume of each of the sections 381, 382 may be smaller than the sectional void volume of section 380 due to the total number of apertures 364 being different in one or more of the sections 380-383. In this manner, the flow rate and pressure of gas being exhausted through the flange 361 may be equalized by constricting the amount of gas that can flow through section 383 compared to the sections 380-382.

In another example, the apertures may be uniformly distributed within each section along the flange rather than one section of the flange including a larger number of apertures than another. In this example, to provide a uniform gas flow rate and pressure through the flange, the void volume of each aperture (i.e., the shape and/or size of the respective aperture) may be adjusted such that the void volume of each aperture, or the sectional void volume of the apertures in a section above the gas exhaust outlet is decreased relative to the sections adjacent to or spaced apart from the outlet. Accordingly, each section of the flange may have a generally equal number of apertures but a different sectional void volume due to each of the apertures, or each section, having a different void volume. In this manner, the gas flow rate and the pressure through the flange may be uniform due to a varying void volume along the flange. However, it should be understood that, in other embodiments, the flange may define a uniform distribution of apertures along the flange, and for each void volume to be equivalent (e.g., where the outlet is equally distanced from each aperture).

In other embodiments, there may be any number of sections that each include a different sectional void volume. In yet other embodiments, there may be a gradual change in void volume from one point along the flange to another rather than distinct sections that each have a particular sectional void volume. In yet other embodiments, there may be multiple sections along the flange that each includes an equivalent void volume. For example, there may be two gas exhaust outlets positioned adjacent opposite sections of the flange. In this example, the sectional void volume of those sections of the flange adjacent the gas exhaust outlets may be equivalent to each other but may be different to the section void volume of the other sections of the flange to ensure that there is a uniform gas flow rate and pressure entering the pumping ring.

In some embodiments, the chamber body, pumping ring, and the pumping support are not separate components. Rather, these components may be monolithically formed together. In other embodiments, only two of those components may be monolithically formed together (e.g., the pumping ring and the chamber body, the pumping ring and the pumping support, or the pumping support and the chamber body).

Nonetheless, referring back to the lid 316 of lid assembly 306, the lid 316 may be coupled to a top end 301 of the chamber body 302 (e.g., through welding, adhesive, releasable or non-releasable fastening, or the like). The lid 316 may include a central opening sized and shaped to accommodate one or more of the other lid assembly 306 components (e.g., the gas box 312, faceplate 315, and blocker plate 313). The lid 316 may be coupled to a ground such that the lid 316 does not have an electrical charge. In embodiments, the lid 316 may have an internal diameter of greater than or about 7 inches, such as greater than or about 8 inches, such as greater than or about 9 inches, such as greater than or about 10 inches, such as greater than or about 11 inches, such as greater than or about 12 inches such as greater than or about 13 inches, such as greater than or about 14 inches, or such as less than or about 21 inches, such as less than or about 20 inches, such as less than or about 19 inches, such as less than or about 18 inches, such as less than or about 17 inches, such as less than or about 16 inches such as less than or about 15 inches, or any ranges or values therebetween.

In embodiments, the gas box 312, faceplate 315, and blocker plate 313 may help to facilitate the distribution of process gas (e.g., precursor) from a gas source fluidly coupled to the gas box 312 to the processing region 320. Nonetheless, a blocker plate 313 may be disposed between the gas box 312 and the faceplate 315. A radio frequency (“RF”) source may be coupled with the faceplate 315 to facilitate generating a plasma region between the faceplate 315 and the substrate support 304. In some embodiments, the RF source may be coupled with other portions of the chamber body 302 to facilitate plasma generation, such as the faceplate 315. The faceplate 315 may have an outer diameter of greater than or about 9 inches, such as greater than or about 10 inches, such as greater than or about 11 inches, such as greater than or about 12 inches, such as greater than or about 13 inches, or may have an outer diameter of less than or about 16 inches, such as less than or about 15 inches, such as less than or about 14 inches.

Turning to FIG. 4, the isolator 390 may be disposed on an upper surface 317a of rim 317 of lid 316. The isolator 390 may form a support for the seating of the faceplate 315. The isolator 390 may be partially received within the chamber body 302. The isolator 390 may be formed from a ceramic, plastic, or other thermally insulating material. The isolator 390 includes an isolator base 391, isolator wall 392, and isolator extension 393. The isolator base 391 and the isolator wall 392 may be disposed at an angle greater than or about 70°, such as greater than or about 75°, such as greater than or about 80°, such as greater than or about 85°, such as greater than or about 87.5°, or an angle less than or about 110°, such as less than or about 105°, such as less than or about 100°, such as less than or about 95°, such as less than or about 92.5°, or any ranges or values therebetween, relative to one another. In embodiments, the isolator base 391 may be generally orthogonal to the isolator wall 392. In this manner, the isolator base 391 and the isolator wall 392 may define a corner, in embodiments, facing exterior to the isolator 390 to provide a seating surface corresponding to a rim 317 of lid 316, and may be sized and shaped to receive a lower surface 318 extending around the outer radius of faceplate 315.

The isolator extension 393 may extend from the isolator wall 392 at an angle greater than or about 15°, greater than or about 20°, greater than about 25°, greater than or about 30° greater than or about 35°, greater than or about 40°, greater than or about 42.5°, or may include an angle less than or about 75°, such as less than or about 70°, such as less than or about 65°, such as less than or about 60°, such as less than or about 55°, such as less than or about 50°, such as less than or about 47.5°, or any ranges or values therebetween, and may be positioned substantially, or entirely, within the chamber body 302. The isolator extension 393 may be positioned between the lid 316 and a bottom portion 319 of the faceplate 315 received within the chamber body 302. The isolator extension 393 may extend a distance within the chamber body such that a tip 396 of the isolator extension 393 is generally coplanar with a bottom surface 397 of the faceplate 315 extending within the chamber body 302. However, in other embodiments, the isolator extension may extend past the bottom surface of the faceplate. In this manner, the isolator extension 393 may act as a barrier between the lid 316 and the faceplate 315 within the chamber body 302. In other words, the isolator extension 393 is positioned between the lid 316 and the faceplate 315 to isolate the lid 316 from the faceplate 315 along a radial direction from the center of the chamber body 302. In such a manner, the flow of process gasses and a direct electrical pathway between the lid 316 and the faceplate 315 is prevented (e.g., due at least in part to the removal of the line-of-sight, or straight flow path/electrical pathway, between the lid 316 and the faceplate 315), reducing or even eliminating parasitic light up. The tip 396 of the isolator extension 393 may have an internal diameter greater than or about 9 inches, greater than or about 9.5 inches, such as greater than or about 10 inches, such as greater than or about 10.5 inches such as greater than or about 11 inches, such as greater than or about 11.5 inches such as greater than or about 12 inches, such as greater than or about 12.5 inches, such as greater than or about 13 inches, or may have an internal diameter of less than or about 16 inches, such as less than or about 15.5 inches, such as less than or about 15 inches, such as less than or about 14.5 inches, such as less than or about 14 inches, such as less than or about 13.5 inches, or any ranges or values therebetween.

For instance, if an isolator extension were not present, the bottom portion of the faceplate may be exposed by line-of-sight to the lid. Such direct exposure may be a problem as, in use, when the faceplate is charged by the RF source to create a plasma within the processing region, plasma may arc between the faceplate and the lid to form parasitic plasma. However, by utilizing an isolator extension 393, according to the present technology, positioned between the bottom portion 319 of the faceplate 315 and the lid 316, parasitic plasma formation is minimized or even eliminated.

The isolator extension 393 may define an interior surface 394 facing the faceplate 315. The interior surface 394 may be angled to minimize the gap between the isolator extension 393 and the faceplate 315. In this manner, gas within the processing region 320 may be directed along a particular gas flow path (e.g., the gas flow path A as indicated by the arrows in FIG. 4) rather than infiltrating between the isolator 390 and the faceplate 315.

With continued reference to FIG. 4, process gas may be evacuated from the processing region 320 along a gas flow path A downstream to the outlet 352. The exhaust system may activate to begin pumping gas from within the processing region 320 through to the vacuum source the exhaust system is coupled to. Accordingly, the gas may flow from the processing region 320 downstream along the flow path A to the vacuum. The gas flow path A may include pumping the gas from the processing region 320, around the ring body 363, above transition portion 362, and down through the plurality of apertures 364 in pumping ring 360. Specifically, the gas may flow from the processing region 320 at an angle through the space defined between the isolator extension 393 and the transition portion 362. From this space, the gas may flow laterally above flange 361 and down through apertures 364. Moreover, the gas may flow down through the plurality of apertures 364 into the top opening 379 and pumping channel 372 of the pumping support 370. The gas may then flow within and about the pumping channel 372 and down through the pumping support exit 373 to flow into the gas exhaust outlet 352. From the gas exhaust outlet 352, the gas may then flow into the vacuum source.

Such a flow path is beneficial as the multi-angled flow path and vertical flow of gas within the processing region 320 minimizes the unintended flow of undesirable byproducts (e.g., precursor particles) backwards (e.g. into processing region 320) through pumping ring 360 during changes in processing conditions (e.g., changes in pressure). Thus, the risk that undesirable byproducts within the pumping ring 360 or gas flow path A may inadvertently revert into the processing region 320 and interact with a substrate being processed. Namely, as discussed above, conventional systems with laterally extending pumping paths through a pumping ring having little to no changes in the direction of the flow path, provide for little to no resistance paths for precursor particles. Thus, such precursor particles can be easily reverted back into the processing region. As noted above, this is additionally problematic with horizontally extending pumping paths, as the flow path extends directly over a substrate being processed.

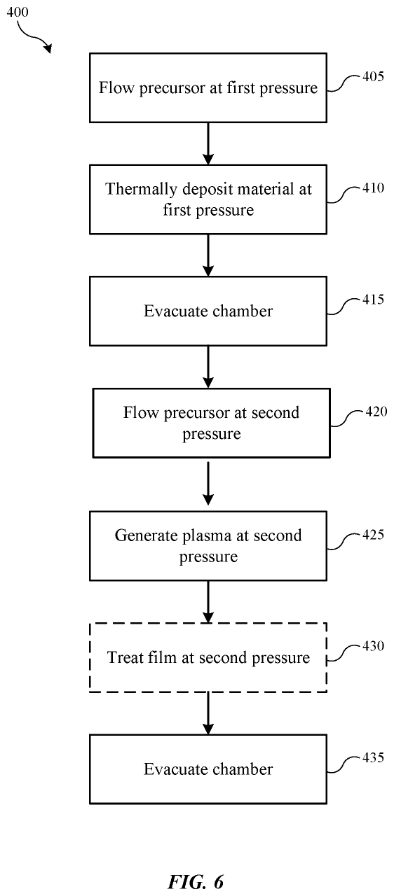

FIG. 6 shows operations of an exemplary method 400 of semiconductor processing according to some embodiments of the present technology. The method may be performed in a variety of processing chambers, including processing system 300 described above, which may include a gas distribution assembly and other features according to embodiments of the present technology. Method 400 may include a number of optional operations, which may or may not be specifically associated with some embodiments of methods according to the present technology.

Method 400 may include a processing method that may include operations for forming a hardmask film or other deposition operations. The method may include optional operations prior to initiation of method 400, or the method may include additional operations. For example, method 400 may include operations performed in different orders than illustrated. In some embodiments, method 400 may include flowing one or more precursors into a processing chamber at operation 405 at a first pressure. The first pressure may include a pressure greater than about 200 Torr, such as greater than or about 300 Torr, such as greater than about 400 Torr, such as greater than or about 500 Torr, or any ranges or values therebetween. For example, the precursor may be flowed into a chamber, such as included in system 300, and may flow the precursor through one or more of a gasbox, a blocker plate, or a faceplate, prior to delivering the precursor into a processing region of the chamber. In some embodiments the precursor may be or include a carbon-containing precursor, or any precursor as known in the art.

At operation 405, a plasma may be generated of the precursors within the processing region, such as by providing RF power to the faceplate to generate a plasma. Material formed in the plasma, such as a carbon-containing material, may be deposited on the substrate at operation 410 In embodiments, operation 410 may be a thermal deposition operation. After deposition operation 410, the process gasses, including the precursor may be evacuated from the chamber at operation 415, such as through a pumping ring 360, pumping channel, and utilizing a lid assembly as discussed above, at a very high level of efficiency as discussed above.

After evacuation, a precursor, which may be the same precursor or a different precursor, may be flowed into the chamber at a second pressure at operation 420, such as by altering the pressure of the chamber. The second pressure may be greater or lower than the first pressure. The second pressure may include a pressure less than about 100 Torr, such as less than or about 75 Torr, such as less than about 50 Torr, such as less than or about 25 Torr, such as less than or about 10 Torr, such as less than or about 5 Torr, or any ranges or values therebetween. However, it should be clear that the values of the first pressure and second pressure may be interchanged, as the high pressure operation may occur prior to the low pressure operation. Surprisingly, due at least in part to the pumping ring, pumping channel, and/or lid assembly of the pending claims, little to no defects are formed on a substrate. Namely, due to the multi-angled flow path and vertical flow channel, even drastic changes in pressure do not result in the flow-back of contaminants. Nonetheless, in embodiments, methods may include generating a plasma at the second pressure at operation 425 and depositing material on the substrate at the second pressure at. Moreover, it should be clear that, more than two evacuations and changes in pressure are possible. In embodiments, the film formed at operation 425 may be treated at operation 430 with treatment methods as known in the art. Nonetheless, after deposition at the second pressure, the chamber may be evacuated 435, such as through a pumping ring 360, pumping channel, and utilizing a lid assembly as discussed above, at a very high level of efficiency as discussed above.

The subject matter of embodiments of the present invention is described here with specificity to meet statutory requirements, but this description is not necessarily intended to limit the scope of the claims. The claimed subject matter may be embodied in other ways, may include different elements or steps, and may be used in conjunction with other existing or future technologies. This description should not be interpreted as implying any particular order or arrangement among or between various steps or elements except when the order of individual steps or arrangement of elements is explicitly described.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A substrate processing chamber, comprising:
a chamber body including a first end and a second end;
a lid coupled to the first end of the chamber body;
an isolator disposed on an upper surface of the lid;
a faceplate disposed on an upper surface of the isolator;
a substrate support disposed on a shaft extending through the second end of the chamber body, wherein a processing region is defined between the substrate support and the faceplate;
a pumping ring positioned within the chamber body, wherein the pumping ring comprises a flange extending in a plane generally parallel with a top surface of the substrate support, the flange defining a plurality of apertures; and
an exhaust outlet in fluid communication with a system foreline and the plurality of apertures.

2. The substrate processing chamber of claim 1, wherein:
the flange comprises a first section and a second section;
the first section defines a first portion of apertures of the plurality of apertures and the second section defines a second portion of apertures of the plurality of apertures; and
the first section defines a first sectional void volume based on the first portion of apertures and the second section defines a second sectional void volume based on the second portion of apertures, wherein the first sectional void volume is less than the second sectional void volume.

3. The substrate processing chamber of claim 2, wherein the first section is closer to the exhaust outlet than the second section.

4. The substrate processing chamber of claim 3, wherein the first portion of apertures includes a lesser number of apertures than the second portion of apertures.

5. The substrate processing chamber of claim 3, wherein the first portion of apertures includes an equal number of apertures as the second portion of apertures.

6. The substrate processing chamber of claim 5, wherein each aperture of the first portion of apertures includes a lesser void volume than each aperture of the second portion of apertures.

7. The substrate processing chamber of claim 1, further comprising a pumping support disposed between the pumping ring and the chamber body, wherein the pumping support defines:
a pumping channel in fluid communication with the plurality of apertures; and
a pumping exit in fluid communication with the pumping channel and the system foreline.

8. The substrate processing chamber of claim 7, wherein a bottom surface of the isolator is generally coplanar with a bottom surface of the faceplate.

9. The substrate processing chamber of claim 8, wherein:
the isolator includes an isolator body and an isolator extension extending from the isolator body at an angle, wherein the isolator extension forms the bottom surface of the isolator.

10. A gas distribution assembly, comprising:
a pumping ring comprising a ring body, a transition portion, and a flange extending transverse from the ring body, wherein:
the flange defines a plurality of apertures extending from a top surface of the flange to a bottom surface of the flange;
the flange includes a first section and a second section;
the first section of the flange defines a first portion of apertures of the plurality of apertures and the second section of the flange defines a second portion of apertures of the plurality of apertures; and
the first section defines a first sectional void volume based on the first portion of apertures and the second section defines a second sectional void volume based on the second portion of apertures, wherein the first sectional void volume is less than the second sectional void volume; and
an isolator comprising a base portion, a body portion, and an extension portion,
wherein the extension portion of the isolator is disposed above and generally parallel to the transition portion of the pumping ring.

11. The gas distribution assembly of claim 10, wherein at least one aperture of the plurality of apertures includes a frustoconical shape.

12. The gas distribution assembly of claim 11, wherein:
the flange includes a top surface and a bottom surface; and
the top surface defines a first width of the at least one aperture and the bottom surface defines a second width of the at least one aperture, the first width being smaller than the second width.

13. The gas distribution assembly of claim 11, wherein the first portion of apertures includes a lesser number of apertures than the second portion of apertures.

14. The gas distribution assembly of claim 11, wherein the first portion of apertures includes an equal number of apertures as the second portion of apertures.

15. The gas distribution assembly of claim 14, wherein each aperture of the first portion of apertures includes a lesser void volume than each aperture of the second portion of apertures.

16. The gas distribution assembly of claim 10, wherein:
the flange includes a third section positioned between the first and second sections;
the third section defining a third portion of apertures of the plurality of apertures; and
the third section defines a third sectional void volume based on the third portion of apertures, wherein the third sectional void volume is less than the second sectional void volume and greater than the first sectional void volume.

17. The gas distribution assembly of claim 16, wherein the third portion of apertures includes a lesser number of apertures than the second portion of apertures and a greater number than the first portion of apertures.

18. The gas distribution assembly of claim 16, wherein the third portion of apertures includes an equal number of apertures as at least one of the first portion of apertures and the second portion of apertures.

19. The gas distribution assembly of claim 18, wherein each aperture of the third portion of apertures includes a lesser void volume than each aperture of the at least one of the first or second portion of apertures.

20. A method of semiconductor processing comprising:
flowing a carbon-containing precursor into a processing chamber, wherein the processing chamber comprises:
a chamber body including a first end and a second end;
a lid coupled to the first end of the chamber body;
an isolator disposed on an upper surface of the lid;
a faceplate disposed on an upper surface of the isolator;
a substrate support disposed on a shaft extending through the second end of the chamber body, wherein a processing region is defined between the substrate support and the faceplate;
a pumping ring positioned within the chamber body, wherein the pumping ring comprises a flange extending in a plane generally parallel with a top surface of the substrate support, the flange defining a plurality of apertures; and
an exhaust outlet in fluid communication with a system foreline and the plurality of apertures; and
exhausting a gas from the chamber body of the processing chamber via the pumping ring to the exhaust outlet.
